(19) United States
(12) Patent Application Publication
(10) Pub. No.: US 2008/0305595 A1
(43) Pub. Date: Dec. 11, 2008

(54) METHODS OF FORMING A SEMICONDUCTOR DEVICE INCLUDING OPENINGS

(75) Inventor: Hyung-Joon Kwon, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/131,293

(22) Filed: Jun. 2, 2008

(30) Foreign Application Priority Data
Jun. 7, 2007 (KR) 2007-55568

(51) Int. Cl. H01L 21/8234; H01L 21/306

(52) U.S. Cl. 438/279; 438/689; 257/E21.62; 257/E21.215

(57) ABSTRACT

There is provided a method of forming a semiconductor device. According to the method, a gate pattern having a capping insulating layer is formed on a substrate, a first etch stop layer is conformably formed. A first interlayer insulating layer having a planarized upper surface, a second etch stop layer and a second interlayer insulating layer are sequentially formed on the first etch stop layer. A first opening and a second opening are formed. The first opening penetrates the second interlayer insulating layer, the second etch stop layer, the first interlayer insulating layer, the first etch stop layer and the capping insulating pattern to expose the gate electrode, and the second opening penetrates the second interlayer insulating layer, the second etch stop layer, the first interlayer insulating layer and the first etch stop layer to expose the substrate. The forming the first and second openings includes at least one selective etching process and a nonselective etching process.

### CROSS-REFERENCE TO RELATED APPLICATIONS

This U.S. non-provisional patent application claims priority under 35 U.S.C. §119 of Korean Patent Application No. 2007-55568, filed on Jun. 7, 2007, the entire contents of which are hereby incorporated by reference.

### BACKGROUND OF THE INVENTION

The present invention disclosed herein relates generally semiconductor devices, and more particularly, to a method of forming semiconductor devices.

Generally, a semiconductor device may have a stacking structure to get a high integration. In a semiconductor device, a bottom conductor and a top conductor insulated from each other may be electrically connected through a contact hole. That is, an oxide layer is formed on a substrate including the bottom conductor. The oxide layer is patterned to form the contact hole exposing the bottom conductor. The top conductor is formed on the oxide layer after forming conductive material that fills the contact hole. The top conductor may be in contact with the conductive material that fills the contact hole and be electrically connected to the bottom conductor. A plurality of contact holes may be formed on an oxide layer. The oxide layer may vary in thickness. The oxide layer may be over etched to completely penetrate all the contact holes.

As the integration of semiconductor device increases, a depth of a contact hole may be increased. Thus, due to the over etching of the oxide layer, the bottom conductor which is exposed by the contact hole may be damaged to cause a malfunction of a semiconductor device. For instance, in the case that the contact holes expose source/drain regions formed on the substrate, the source/drain regions may be damaged by the over etching of the oxide layer to bring about a leakage current.

Contact holes having different depths may be formed on the same level by a topology of bottom structure. That is, upper surfaces of the contact holes may be coplanar but lower surfaces of the contact holes may be located at places having different heights. It may be difficult to etch the contact holes having different depths. For instance, when first and second contact holes having different depths are formed on the same level, thicknesses and/or types of etched material layers for the first contact hole may be different from those of the second contact hole. In the case that the first and second contact holes are simultaneously formed, the bottom conductors exposed by the first contact hole and/or second contact hole may be damaged by a difference in an amount of etching and/or etched material. As a result, a characteristic of a semiconductor device may be deteriorated. To solve the above problem, the first and second contact holes may be sequentially formed. However, in this case, a first exposure process for defining the first contact hole and a second exposure process for defining the second contact hole are required. Since a variety of exposure processes are performed, a manufacturing process of a semiconductor device may become complicated. Also, since an align margin between various exposure processes is required, a manufacturing process of a semiconductor device may become difficult. As a result, productivity and a characteristic of a semiconductor device may be degraded.

### SUMMARY OF THE INVENTION

Example embodiments provide a method of forming a semiconductor device which may include forming a gate pattern including a gate insulating layer, a gate electrode and a capping insulating pattern that are sequentially stacked on a substrate; conformably forming a first etch stop layer on the substrate; sequentially forming a first interlayer insulating layer having a planarized upper surface, a second etch stop layer and a second interlayer insulating layer on the first etch stop layer; and forming a first opening and a second opening. The first opening penetrates the second interlayer insulating layer, the second etch stop layer, the first interlayer insulating layer, the first etch stop layer and the capping insulating pattern to expose the gate electrode. The second opening penetrates the second interlayer insulating layer, the second etch stop layer, the first interlayer insulating layer and the first etch stop layer to expose the substrate. Forming the first and second openings includes at least one selective etching process and a nonselective etching process. The nonselective etching process etches the second etch stop layer, the first interlayer insulating layer, the first etch stop layer and the capping insulating pattern at the same etch rate.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIGS. 1 to 8 are cross sectional views illustrating a method of forming a semiconductor device including a contact structure in accordance with example embodiments of the present invention; and

FIG. 9 is a flowchart illustrating a method of forming openings in accordance with example embodiments of the present invention.

### DETAILED DESCRIPTION OF PREFERRED EMBODIMENTS

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments of the present invention may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

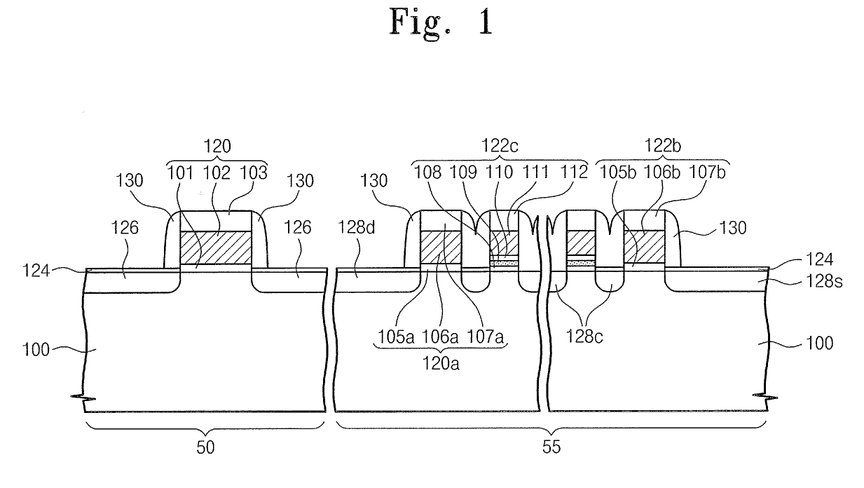

FIGS. 1 to 8 are cross sectional views illustrating a method of forming a semiconductor device including a contact structure in accordance with example embodiments of the present invention.

Referring to FIG, 1, a semiconductor substrate 100 (hereinafter it is referred to as substrate) including a peripheral region 50 and a cell array region 55 is provided. A device isolation layer (not shown) is formed in the substrate 100 to define a peripheral active region in the peripheral region 50 and a cell string active region in the cell array region 55. The cell string active region may be a line shape extending along one direction. FIG. 1 is a cross sectional view taken along the peripheral active region and the cell string active region. The peripheral active region is a portion of the substrate 100 within the peripheral region 50 surrounded by the device isolation layer and the cell string active region is a portion of the substrate 100 within the cell array region 55 surrounded by the device isolation layer.

A peripheral gate pattern 120 is formed on the peripheral active region. First and second selective gate lines 122a and 122b are formed to be in parallel to each other on the cell string active region and cell gate lines 122c are formed to be in parallel to each other on the cell string active region between the first and second selective gate lines 122a and 122b. The peripheral gate pattern 120, the first and second selective gate lines 122a and 122b and the cell gate line 122c may be simultaneously formed by one patterning process.

18] The peripheral gate pattern 120 may include a peripheral gate insulating layer 101, a peripheral gate electrode 102 and a peripheral capping insulating pattern 103 that are sequentially stacked. The first selective gate line 122a [120a?] may include a first selective gate insulating layer 105a, a first selective gate electrode 106a and a first selective capping insulating pattern 107a that are sequentially stacked, and the second selective gate line 122b may include a second selective gate insulating layer 105b, a second selective gate electrode 106b and a second selective capping insulating pattern 107b that are sequentially stacked. The cell gate line 122c may include a tunnel insulating layer 108, a charge storage layer 109, a blocking insulating layer 110, a control gate electrode 111 and a cell capping insulating pattern 112.

The tunnel insulating layer 108 may be formed of an oxide layer (e.g., a thermal oxide layer). The charge storage layer 109 may be formed of material that can store charges. For instance, the charge storage layer 109 may be formed of doped polysilicon or undoped polysilicon. Alternatively, the charge storage layer 109 may be formed of insulating material (for instance, insulating material including nitride and/or nanocrystals) including traps of a deep level that can store charges.

The blocking insulating layer 110 may include at least one of an oxide layer having a thickness greater than the tunnel insulating layer 108, an ONO (oxide-nitride-oxide) layer and/or a high dielectric layer having a dielectric constant higher than the tunnel insulating layer 108. The high dielectric layer may be an insulating metal oxide layer such as an aluminum oxide layer or a hafnium oxide layer etc. The control gate electrode 111 may be formed of conductive material. The control gate electrode 111 may include at least one of doped polysilicon and material containing conductive metal. The material containing conductive metal may be at least one of metal (e.g. tungsten or molybdenum), conductive metal nitride (e.g. nitride titanium or nitride tantalum) and metal silicide (e.g. tungsten silicide or cobalt silicide). An upper portion of the control gate electrode 111 may be formed of the above mentioned material containing conductive metal.

The peripheral gate insulating layer 101 may be formed of an oxide layer. The peripheral gate electrode 102 may include the same material as the control gate electrode 111. An upper portion of the peripheral gate electrode 102 may be formed of the above mentioned material containing conductive metal. In the case that the charge storage layer 109 is formed of doped polysilicon, the peripheral gate electrode 102 may further include the same material as the charge storage layer 109. The peripheral gate insulating layer 101 may be formed to have a thickness greater than the tunnel insulating layer 108.

The first and second selective gate insulating layers 105a and 105b may be formed of an oxide layer. The first and second selective gate insulating layers 105a and 105b may be formed to have the same thickness as the tunnel insulating layer 108. That is, the first and second selective gate insulating layers 105a and 105b and the tunnel insulating layer 108 may be simultaneously formed. Alternatively, the first and second selective gate insulating layers 105a and 105b may be formed to have a thickness greater than the tunnel insulating layer 108. In this case, the first and second selective gate insulating layers 105a and 105b may be formed to have the same thickness as the peripheral gate insulating layer 101 or to have a thickness less than the peripheral gate insulating layer 101.

In the case that the charge storage layer 109 is formed of insulating material including the above mentioned traps of a deep level, the tunnel insulating layer 108, the charge storage layer 109 and the blocking insulating layer 110 may extend sideward to be connected to the tunnel insulating layer 108, the charge storage layer 109 and the blocking insulating layer 110 of the other adjacent cell gate line 122c. Also, in the case that the charge storage layer 109 is formed of insulating material including the traps of a deep level, the first and second selective gate insulating layers 105a and 105b may include all the same materials as the tunnel insulating layer 108, the charge storage layer 109 and the blocking insulating layer 110.

The peripheral, first selective, second selective and cell capping insulating patterns 103, 107a, 107b and 112 may be formed of the same material.

Dopant ions are implanted into the peripheral active region of both sides of the peripheral gate pattern 120 to form peripheral source/drain regions 126. Dopant ions are implanted into the cell string active region of both sides of the first and second selective gate lines 122a and 122b and the cell gate lines 122c to form a common drain region 128d, a common source region 128s and cell source/drain regions 128c. The common drain region 128d is formed in the cell string active region at a side of the first selective gate line 122a and the common source region 128s is formed in the cell string active region at a side of the second selective gate line 122b. The cell source/drain regions 128c are formed in the cell string active region at both sides of the cell gate line 122c. The gate lines 122a, 122b and 122c and the cell source/drain region 128c are disposed between the common drain region 128d and the common source region 128s.

Dopants in the peripheral source/drain regions 126 and dopants in the common drain/source regions 128d and 128s may be the same type. In this case, the peripheral source/drain regions 126 and the common drain/source regions 128d and 128s may be simultaneously formed. Alternatively, dopants in the peripheral source/drain regions 126 and dopants in the common drain/source regions 128d and 128s may be a different type. In this case, the peripheral source/drain regions 126 and the common drain/source regions 128d and 128s may be sequentially formed. At this time, the peripheral source/drain regions 126 may be first formed or the common drain/source regions 128d and 128s may be first formed.

A buffer insulating layer 124 may be formed on the substrate 100. The buffer insulating layer 124 may be formed on the peripheral active region of both sides of the peripheral gate pattern 120 and on the cell string active region of both sides of the gate lines 122a, 122b and 122c. The buffer insulating layer 124 may be formed of a thermal oxide layer. The buffer insulating layer 124 may be formed immediately after the peripheral gate pattern 120 and the gate lines 122a, 122b and 122c are formed. That is, the buffer insulating layer 124 may be formed before the peripheral source/drain regions 126, the common drain/source regions 128d and 128s and the cell source/drain region 128c are formed. In this case, the buffer insulating layer 124 may be served as a buffer layer of an ion implantation process for forming the above mentioned regions 126, 128d, 128s and 128c. The buffer insulating layer 124 may be formed by a gate oxidation process. Alternatively, the buffer insulating layer 124 may be formed after the above mentioned regions 126, 128d, 128s and 128c are formed. The buffer insulating layer 124 may be formed by a chemical vapor deposition (CVD) process.

Gate spacers 130 may be formed on both sidewalls of the peripheral gate pattern 120 and the gate lines 122a, 122b and 122c. The gate spacer 130 may be formed of an oxide layer, a nitride layer and/or an oxynitride layer.

After the gate spacer 130 is formed, a first high dose ion implantation process may be performed using the gate spacer 130 and the peripheral gate pattern 120 as a mask. Thus, the peripheral source/drain regions 126 may be formed to have a lightly doped drain (LDD) structure. Also, after the gate spacer 130 is formed, a second high dose ion implantation process may be further performed on the common drain/source regions 128d and 128s. Thus, the common drain/source regions 128d and 128s may be formed to have a lightly doped drain (LDD) structure. In the case that the same type dopants are implanted into the peripheral source/drain regions 126 and the common drain/source regions 128d and 128s, the first and second high dose ion implantation processes may be simultaneously performed. Alternatively, in the case that different type dopants are implanted into the peripheral source/drain regions 126 and the common drain/source regions 128d and 128s, the first and second high dose ion implantation processes may be sequentially performed.

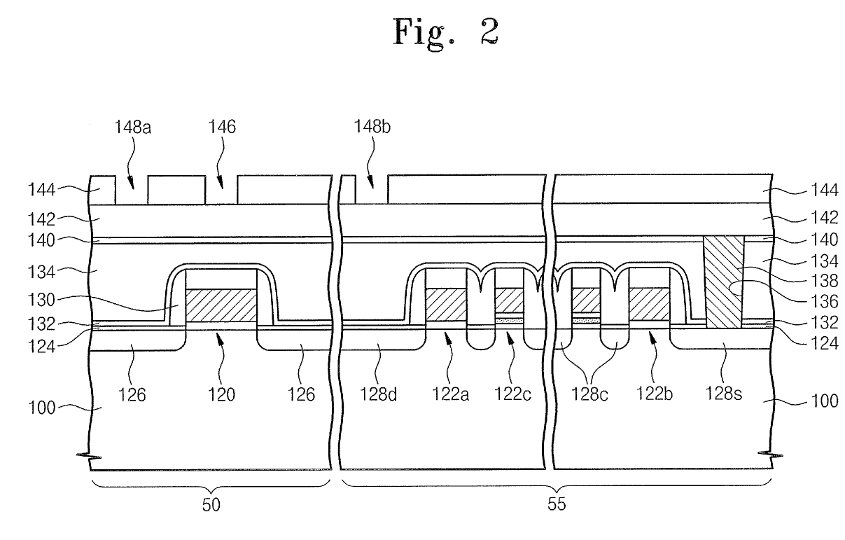

Referring to FIG. 2, subsequently, a first etch stop layer 132 may be conformably formed on the substrate 100. The first etch stop layer 132 may be formed by a chemical vapor deposition (CVD) process. A first interlayer insulating layer 134 is formed on the first etch stop layer 132. It is preferable that an upper surface of the first interlayer insulating layer 134 is planarized. That is, an insulating layer is deposited on the first etch stop layer 132 and an upper surface of the deposited insulating layer is planarized to form the first interlayer insulating layer 134. The planarization process of the deposited insulating layer may be performed by a chemical mechanical polishing (CMP) process. The planarization process of the deposited insulating layer may also be performed by some other methods.

The first interlayer insulating layer 134 may include a plurality of regions which have different thicknesses because it has the planarized upper surface. That is, a thickness of the first interlayer insulating layer 134 on the peripheral source/drain regions 126 and the common drain/source regions 128d and 128s is greater than a thickness of the first interlayer insulating layer 134 on the peripheral gate electrode 102.

The first etch stop layer 132 may be formed of material different from the first interlayer insulating layer 134. For instance, the first interlayer insulating layer 134 is formed of an oxide layer and the first etch stop layer 132 may be formed of a nitride layer (e.g. a silicon nitride layer and/or a silicon oxynitride layer). The first interlayer insulating layer 134 may be a single-layered or a multi-layered. The peripheral, first selective, second selective and cell capping insulating patterns 103, 107a, 107b and 112 may be formed of material different from the first etch stop layer 132. The peripheral, first selective, second selective and cell capping insulating patterns 103, 107a, 107b and 112 may be formed of insulating material having the same etch rate as the first interlayer insulating layer 134. For instance, the peripheral, first selective, second selective and cell capping insulating patterns 103, 107a, 107b and 112 may be formed of oxide layer.

A second etch stop layer 140 is formed on the first interlayer insulating layer 134. The second etch stop layer 140 may be formed of material different from the first interlayer insulating layer 134.

The second etch stop layer 140, the first interlayer insulating layer 134, the first etch stop layer 132 and the buffer insulating layer 124 are sequentially patterned to form a source groove 136 exposing the common source region 128s. The source groove 136 may be parallel to the second selective gate line 122b. A first conductive layer filling the source groove 136 is formed on the substrate 100 and the first conductive layer is planarized down to an upper surface of the second etch stop layer 140 to form a source line 138. The source line 138 is connected to the common source region 128s.

A second interlayer insulating layer 142 is formed on the substrate 100 including the source line 138. The second interlayer insulating layer 142 may cover an upper surface of the source line 138. The second interlayer insulating layer 142 may include oxide. The second interlayer insulating layer 142 may be a single-layered or multi-layered. The second etch stop layer 140 may be formed of material different from the second interlayer insulating layer 142. For instance, the second etch stop layer 140 may be formed of a nitride layer (e.g. a silicon nitride layer and/or a silicon oxynitride layer)

The source groove 136 may be formed before the second etch stop layer 140 is formed. That is, the first interlayer insulating layer 134, the first etch stop layer 132 and the buffer insulating layer 124 are sequentially patterned to form a source groove 136 exposing the common source region 128s. In this case, a first conductive layer filling the source groove 136 is formed and the first conductive layer is planarized down to an upper surface of the first interlayer insulating layer 134 to form a source line 138. Subsequently, the second etch stop layer 140 may be formed. In this case, the upper surface of the source line 138 is covered with the second etch stop layer 140.

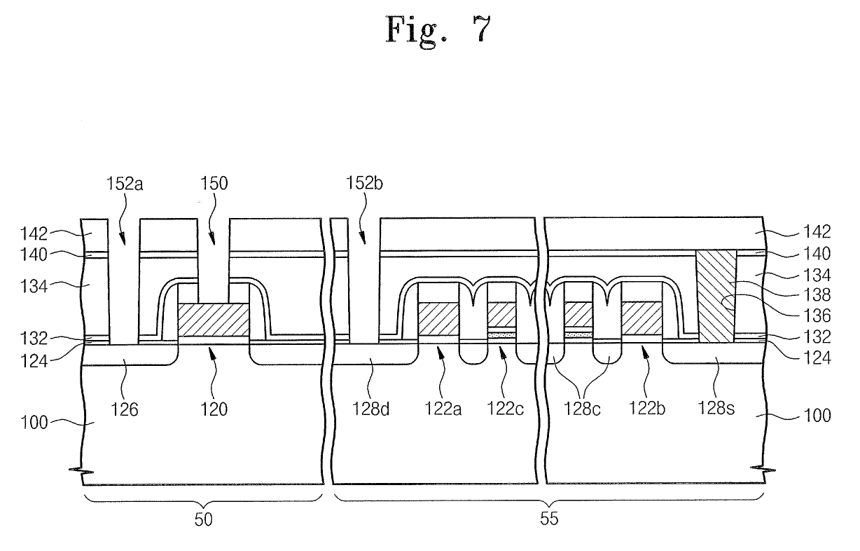

A mask layer is formed on the second interlayer insulating layer 142 and the mask layer is patterned to form a mask pattern 144 including guide openings 146, 148a and 148b. Each of the openings 146, 148a and 148b exposes the second interlayer insulating layer 142. The first guide opening 146 exposes the second interlayer insulating layer 142 over the peripheral gate electrode 102 and the second guide opening 148a exposes the second interlayer insulating layer 142 over the peripheral source/drain regions 126. The third guide opening 148b exposes the second interlayer insulating layer 142 over the common drain region 128d. The first, second and third guide openings 146, 148a and 148b define openings 150, 152a and 152b (FIG. 7) that are formed in subsequent process, respectively. The mask pattern 144 may be formed of material that may be used as a photoresist and/or a hard mask.

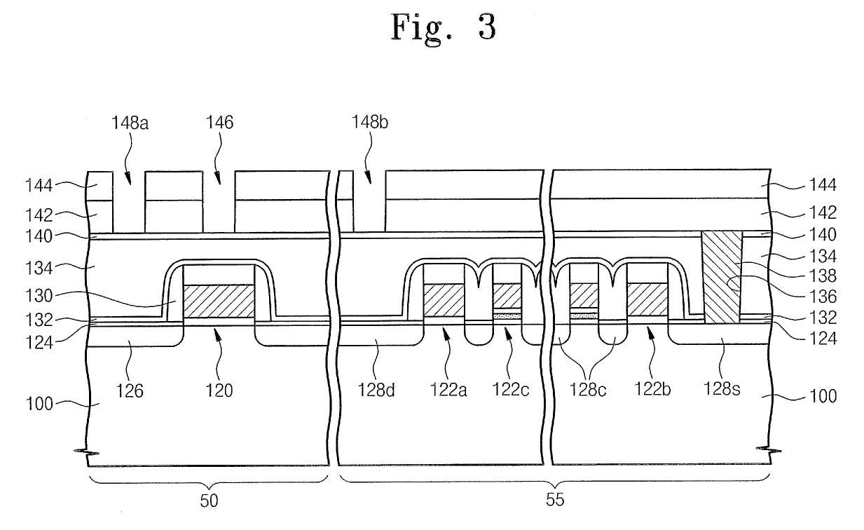

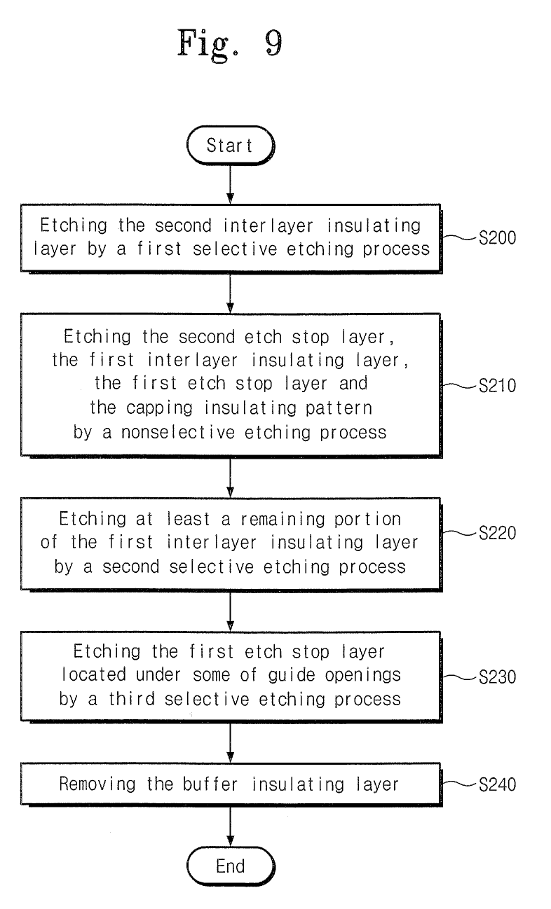

A method of forming the openings 150, 152a and 152b of FIG. 7 will be described in detail with reference to FIGS. 3 through 7 and a flow chart of FIG. 9.

Referring to FIGS. 3 and 9, the second interlayer insulating layer 142 exposed by the guide openings 146, 148a and 148b is etched using the mask pattern 144 as an etching mask by a first selective etching process (S200). The exposed second interlayer insulating layer 142 is etched by the first selective etching process to expose the second etch stop layer 140.

The first selective etching process has an etch selectivity with respect to the second interlayer insulating layer 142 and the second etch stop layer 140. In detail, an etch rate of the second interlayer insulating layer 142 by the first selective etching process is higher than an etch rate of the second etch stop layer 140 by the first selective etching process. Thus, although the second interlayer insulating layer 142 is over etched during the first selective etching process, the first interlayer insulating layer 134 under the guide openings 146, 148a and 148b is protected by the second etch stop layer 140.

Etch selectivity between the second interlayer insulating layer 142 and the second etch stop layer 140 by the first selective etching process may be about 10:1 to about 20:1. It is preferable that the first selective etching process is an anisotropic etching process. In the case that the second interlayer insulating layer 142 is formed of an oxide layer and the second etch stop layer 140 is formed of a nitride layer, an etching gas used in the first selective etching process may include fluoride carbon (e.g. C₄F₆ or C₄F₈). In addition, the etching gas used in the first selective etching process may further include oxygen and/or argon.

A depth between the exposed surface of the second etch stop layer 140 under the second guide opening 148a and an upper surface of the peripheral source/drain region 126 is greater than a depth between the exposed surface of the second etch stop layer 140 under the first guide opening 146 and an upper surface of the peripheral gate electrode 102. Similarly, a depth between the exposed surface of the second etch stop layer 140 under the third guide opening 148b and an upper surface of the common drain region 128d is greater than the depth between the exposed surface of the second etch stop layer 140 under the first guide opening 146 and the upper surface of the peripheral gate electrode 102. The first interlayer insulating layer 134 under the second and third guide openings 148a and 148b is thicker than the first interlayer insulating layer 134 under the first guide opening 146.

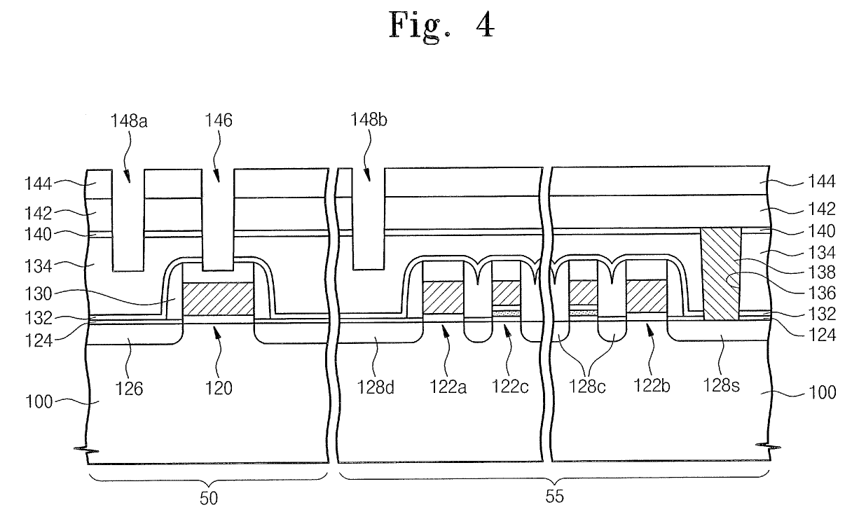

Referring to FIGS. 4 and 9, the exposed second etch stop layer 140, the first interlayer insulating layer 134, the first etch stop layer 132 and the peripheral capping insulating pattern 103 are etched using the mask pattern as an etching mask by a nonselective etching process (S210). The nonselective etching process does not have an etch selectivity. That is, an etch rate of the exposed second etch stop layer 140, the first interlayer insulating layer 134 and the peripheral capping insulating pattern 103 by the nonselective etching process is substantially the same.

After the nonselective etching process is performed, a portion of the first interlayer insulating layer 134 remains under the second and third guide openings 148a and 148b. In detail, the exposed second etch stop layer 140, the first interlayer insulating layer 134, the first etch stop layer 132 and the peripheral capping insulating pattern 103 under the first guide opening 146 are etched by the nonselective etching process. Alternatively, the exposed second etch stop layer 140 and the first interlayer insulating layer 134 under the second and third guide openings 148a and 148b are etched by the nonselective etching process. This is because the first interlayer insulating layer 134 under the second and third guide openings 148a and 148b is thicker than the first interlayer insulating layer 134 under the first guide opening 146 due to the peripheral gate electrode 102.

After the nonselective etching process is performed, a portion of the peripheral capping insulating pattern 103 may remain under the first guide opening 146. In this case, a remaining portion of the peripheral capping insulating pattern 103 may be thinner than a remaining portion of the first interlayer insulating layer 134 under the second and third guide openings 148a and 148b.

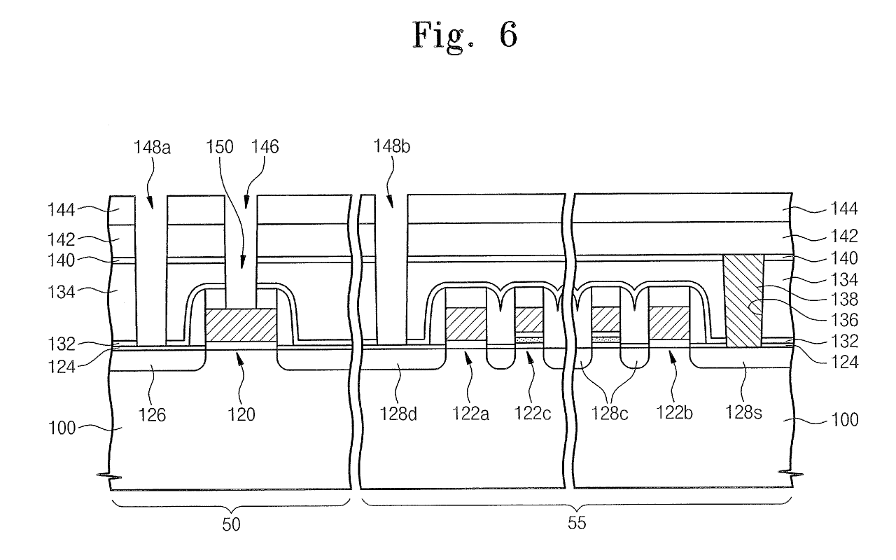

Alternatively, after the nonselective etching process is performed, the peripheral gate electrode 102 under the first guide opening 146 may be exposed. That is, after the nonselective etching process is performed, an opening 150 of FIG. 6 may be formed. In this case, it is preferable that an etch rate of the peripheral gate electrode 102 by the nonselective etching process is lower than an etch rate of the peripheral capping insulating pattern 103 by the nonselective etching process. The peripheral gate electrode 102 may be used to obtain an etch stop point of the nonselective etching process.

It is preferable that the nonselective etching process is an anisotropic etching process. In the case that the first and second etch stop layers 132 and 140 are formed of nitride and the first interlayer insulating layer 134 and the peripheral capping insulating pattern 103 are formed of oxide, an etching gas used in the nonselective etching process may include fluoride hydrogen carbon (e.g. CHF₃ and/or CH₂F₂). In addition, an etching gas used in the nonselective etching process may further include fluoride carbon (e.g. C₄F₆ or C₄F₈), oxygen and/or argon.

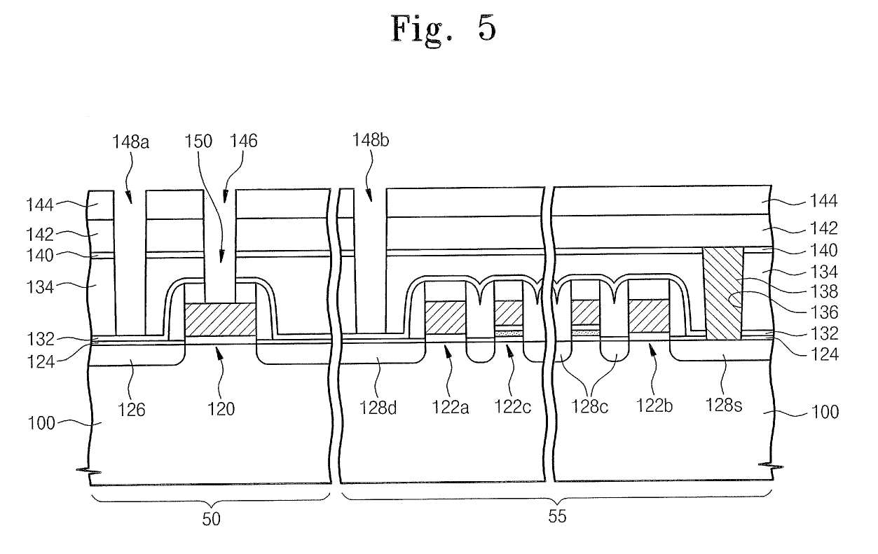

Referring to FIGS. 5 and 9, a remaining portion of the first interlayer insulating layer 134 is etched using the mask pattern 144 as an etching mask by a second selective etching process (S220). As a result, the first etch stop layer 132 under the second and third guide openings 148a and 148b is exposed.

As shown in FIG. 4, in the case that a portion of the peripheral capping insulating pattern 103 remains under the first guide opening 146, the remaining portion of the first interlayer insulating layer 134 and the remaining portion of the peripheral capping insulating pattern 103 are completely removed by the second selective etching process (S220). The first etch stop layer 132 under the second and third guide openings 148a and 148b is exposed and the peripheral gate electrode 102 under the first guide opening 146 is exposed to form a first opening 150. The first opening 150 sequentially penetrates the second interlayer insulating layer 142, the second etch stop layer 140, the first interlayer insulating layer 134, the first etch stop layer 132 and the peripheral capping insulating pattern 103 on the peripheral gate electrode 102 to expose the peripheral gate electrode 102. In this case, it is preferable that an etch rate of the first interlayer insulating layer 134 by the second selective etching process is substantially the same as the etch rate of the peripheral capping insulating pattern 103 by the second selective etching process. Alternatively, it is preferable that an etch rate of the peripheral gate electrode 102 by the second selective etching process is lower than an etch rate of the peripheral capping insulating pattern 103 by the second selective etching process.

It is preferable that the second selective etching process is an anisotropic etching. In the case that the first interlayer insulating layer 134 and the peripheral capping insulating pattern 103 are formed of an oxide layer and the first etch stop layer 132 is formed of a nitride layer, an etching gas used in the second selective etching process may include fluoride carbon (e.g. C₄F₆ or C₄F₈). Also, the etching gas used in the second selective etching process may further include oxygen and/or argon.

Referring to FIGS. 6 and 9, the first etch stop layer 132 exposed under the second and third guide openings 148a and 148b is etched using the mask pattern 144 as an etching mask by a third selective etching process (S230). The buffer insulating layer 124 under the second and third guide openings 148a and 148b is exposed.

The third selective etching process may be an anisotropic etching. An etch rate of first etch stop layer 132 by the third selective etching process is higher than an etch rate of the buffer insulating layer 124 by the third selective etching process. Therefore, the buffer insulating layer 124 may protect the peripheral source/drain regions 126 and the common drain region 128d during the third selective etching process.

Referring to FIGS. 7 and 9, the buffer insulating layer 124 exposed under the second and third guide openings 148a and 148b is removed (S240). Therefore, a second opening 152a exposing the peripheral source/drain regions 126 and a third opening 152b exposing the common drain region 128d are formed. It is preferable that the buffer insulating layer 124 is removed by a wet etching process. Thus, an etching damage of the peripheral source/drain regions 126 and the common drain region 128d exposed by the second and third openings 152a and 152b can be minimized or prevented. In particularly, a plasma damage of the exposed peripheral source/drain regions 126 and the common drain region 128d can be prevented.

The mask pattern 144 is then removed to expose an upper surface of the second interlayer insulating layer 142.

The buffer insulating layer 124 may be omitted. In this case, it is preferable that the third selective etching process is a wet etching. Thus, an etching damage of the exposed peripheral source/drain regions 126 and the common drain region 128d can be minimized or prevented during the third selective etching process. In particularly, a plasma damage of the exposed peripheral source/drain regions 126 and the common drain region 128d can be prevented.

According to the method of forming the openings 150, 152a and 152b described above, one mask pattern 144 can define the first opening 150 having a relatively shallow depth, and the second and third openings 152a and 152b having a relatively deep depth. Therefore, the number of steps of the photolithography process is reduced to simplify a manufacturing process of a semiconductor device.

Also, an etching process for forming the first, second and third openings 150, 152a and 152b may include the selective etching process and the nonselective etching process. An etching damage of the surfaces exposed by the first, second and third openings 150, 152a and 152b may be minimized or prevented. An etching process for forming the first, second and third openings 150, 152a and 152b having a different etching target is simplified to improve the productivity.

In detail, the first selective etching process and the second etch stop layer 140 may buff the etching depth of the first, second and third openings 150, 152a and 152b.

Also, the nonselective etching process may easily etch a relatively dense and various stacked layers 140, 134, 132 and 103 where a portion of the first opening 150 is formed and the stacked layers 140 and 134 where a portion of the second and third openings 152a and 152b is formed. Thus, the etching process for forming the openings 150, 152a and 152b may be simplified.

In addition, when the nonselective etching process is performed, a portion of the first interlayer insulating layer 134 remains under the second and third guide openings 148a and 148b. Accordingly, the first etch stop layer 132 under the second and third guide openings 148a and 148b is protected from the nonselective etching process by the remaining portion of the first interlayer insulating layer 134. Thus, the peripheral source/drain regions 126 and the common drain region 128d can be prevented from being etching damaged during the nonselective etching process.

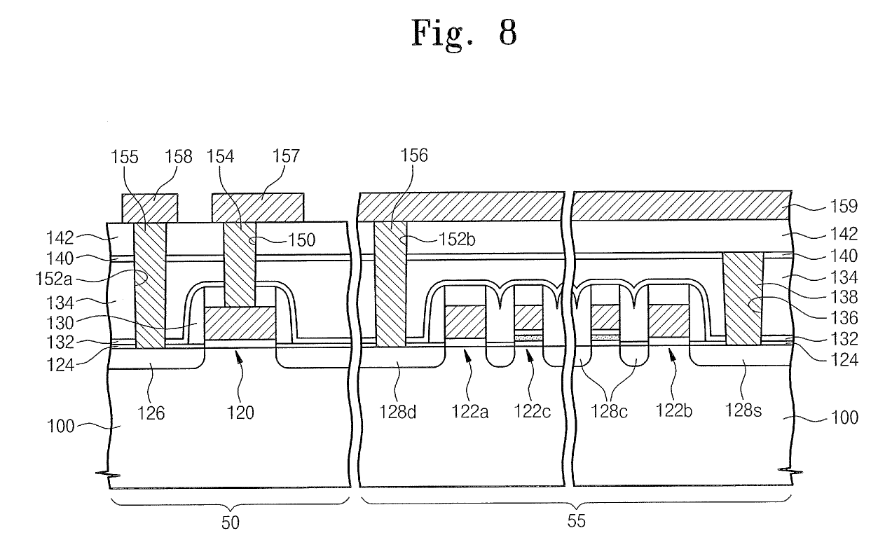

Referring to FIG. 8, a second conductive layer filling the openings 150, 152a and 152b is formed on the substrate 100. And the second conductive layer is planarized down to an upper surface of the second interlayer insulating layer 142. Therefore, first, second and third conductors 154, 155 and 156 are formed to fill the first, second and third openings 150, 152a and 152b, respectively. The first, second and third conductors 154, 155 and 156 may be formed in pillar shape. The first, second and third conductors 154, 155 and 156 may be connected to the peripheral gate electrode 102, the peripheral source/drain regions 126 and the common drain region 128d, respectively.

First, second and third interconnection lines 157, 158 and 159 are formed on the second interlayer insulating layer 142 to be connected to the first, second and third conductors 154, 155 and 156, respectively. The third interconnection line 159 may correspond to a bit line of a NAND-type nonvolatile memory device.

The above embodiments may explain for a NAND-type nonvolatile memory device. However, the present invention should not limited to the embodiments of the NAND-type nonvolatile memory device. The present invention may have application to all semiconductor devices including opening having different depths from each other. For example, the present invention may have application to DRAM device, SRAM device, PRAM device, NOR-type nonvolatile memory device and/or LOSIC device etc.

What is claimed is:

1. A method of forming a semiconductor device, comprising:
forming a gate pattern including a gate insulating layer, a gate electrode and a capping insulating pattern that are sequentially stacked on a substrate;
conformably forming a first etch stop layer on the substrate;
sequentially forming a first interlayer insulating layer having a planarized upper surface, a second etch stop layer and a second interlayer insulating layer on the first etch stop layer; and
forming a first opening and a second opening, the first opening penetrating the second interlayer insulating layer, the second etch stop layer, the first interlayer insulating layer, the first etch stop layer and the capping insulating pattern to expose the gate electrode, and the second opening penetrating the second interlayer insulating layer, the second etch stop layer, the first interlayer insulating layer and the first etch stop layer to expose the substrate,
wherein forming the first and second openings includes at least one selective etching process and a nonselective etching process, and the nonselective etching process etches the second etch stop layer, the first interlayer insulating layer, the first etch stop layer and the capping insulating pattern at the same etch rate.

2. The method of claim 1, wherein a portion of the first interlayer insulating layer where the first opening is formed is thinner than a portion of the first interlayer insulating layer where the second opening is formed.

3. The method of claim 1, wherein forming the first and second openings comprises:
forming a mask pattern having first and second guide openings that expose the second interlayer insulating layer on the second interlayer insulating layer and define the first and second openings, respectively;
etching the exposed second interlayer insulating layer using a first selective etching process to expose the second etch stop layer;
etching the exposed second etch stop layer, the first interlayer insulating layer, the first etch stop layer and the capping insulating pattern using the nonselective etching process to retain at least a portion of the first interlayer insulating layer under the second guide opening;
etching the remaining portion of the first interlayer insulating layer using a second selective etching process; and
etching the first etch stop layer under the first guide opening using a third selective etching process.

4. The method of claim 3, wherein a portion of the capping insulating pattern remains under the first guide opening after performing the nonselective etching process and the remaining portion of the capping insulating pattern is removed by the second selective etching process to expose the gate electrode.

5. The method of claim 4, wherein an etching rate of the first interlayer insulating layer by the second selective etching process is the same as the etching rate of the capping insulating layer by the second selective etching process.

6. The method of claim 4, wherein an etching rate of the gate electrode by the second selective etching process is lower than the etching rate of the capping insulating layer by the second selective etching process.

7. The method of claim 3, wherein the gate electrode is exposed by the nonselective etching process.

8. The method of claim 7, wherein an etching rate of the gate electrode by the nonselective etching process is lower than an etching rate of the capping insulating pattern by the nonselective etching process.

9. The method of claim 3, wherein the first selective etching process, the nonselective etching process and the second selective etching process are anisotropic.

10. The method of claim 3, further comprising:
forming a buffer insulating layer on the substrate where the second opening is formed before forming the first etch stop layer; and
after the first etch stop layer is etched using the third selective etching process, removing an exposed buffer insulating layer to expose the substrate.

11. The method of claim 3, further comprising:
removing the mask pattern after the third selective etching process is performed.

12. The method of claim 1, further comprising:
forming source/drain regions on the substrate of both sides of the gate pattern, wherein the second opening exposes the source/drain region in a side of the gate pattern.

13. The method of claim 1, wherein the substrate includes a peripheral region and a cell array region, wherein the gate pattern is formed on the substrate in the peripheral region and the second opening exposes the substrate in the cell array region.

14. The method of claim 13, before forming the first etch stop layer, further comprising:
forming a first selective gate line and a second selective gate line that are parallel to each other on the substrate of the cell array region and a plurality of cell gate lines that are parallel to each other on the substrate between the first and second selective gate lines: and
forming a common drain region and a common source region on the substrate in the cell array region, the common drain region disposed at a side of the first selective gate line and the common source region disposed at a side of the second selective gate line,
wherein the second opening exposes the common drain region.

15. The method of claim 14, wherein the cell gate line includes a tunnel insulating layer, a charge storage layer, a blocking insulating layer and a control gate electrode that are sequentially stacked.

16. The method of claim 14, before forming the second interlayer insulating layer, further comprising:
successively patterning at least the first interlayer insulating layer and the first etch stop layer in the cell array region to form a source groove exposing the common source region; and
forming a source line filling the source groove and being in contact with the common source region.

17. The method of claim 14, further comprising:
forming source/drain regions in a substrate of both sides of the cell gate pattern.

18. The method of claim 1, further comprising:
forming first and second conductors that fill the first and second openings, respectively.

19. The method of claim 18, wherein upper surfaces of the first and second conductors are coplanar with the upper surface of the second interlayer insulating layer, further comprising:
forming a first interconnection line and a second interconnection line on the second interlayer insulating layer, the first and second interconnection lines being connected to the first and second conductors, respectively.

20. The method of claim 1, before forming the first etch stop layer, further comprising:
forming gate spacers on the both sidewalls of the gate pattern.
